(19) United States
(12) Patent Application Publication
(10) Pub. No.: US 2013/0047056 A1
(43) Pub. Date: Feb. 21, 2013

(54) FLASH MEMORY DEVICE WITH RECTIFIABLE REDUNDANCY AND METHOD OF CONTROLLING THE SAME

(71) Applicants: Jen-Yu Hsu, Hsinchu (TW); Shih-Jia Zeng, Hsinchu (TW); Hsie-Chia Chang, Hsinchu (TW)

(72) Inventors: Jen-Yu Hsu, Hsinchu (TW); Shih-Jia Zeng, Hsinchu (TW); Hsie-Chia Chang, Hsinchu (TW)

(73) Assignee: LITE-ON IT CORPORATION, Taipei (TW)

(21) Appl. No.: 13/658,972

(22) Filed: Oct. 24, 2012

Related U.S. Application Data
(63) Continuation-in-part of application No. 12/761,526, filed on Apr. 16, 2010.

(30) Foreign Application Priority Data
May 5, 2009 (CN) 200910137993.6

(51) Int. Cl. H03M 13/05; H03M 13/19; H03M 13/15

(52) U.S. Cl. 714/773; 714/E11.034

(57) ABSTRACT

A flash memory device connected to a host includes: a flash memory; and a control circuit comprising a first error correcting code unit and a second error correcting code unit. The data length of a redundancy generated by the second error correcting code unit is longer than the data length of a redundancy generated by the first error correcting code unit. The first error correcting code unit is adopted to process with a data transmitted to the flash memory from the host when a damage risk of the flash memory is lower than a specific value; and the first and second error correcting code units are adopted to process with the data transmitted to the flash memory from the host when the damage risk of the flash memory is higher than the specific value.

This is a continuation-in-part application of U.S. application Ser. No. 12/761,526, filed Apr. 16, 2010, the contents of which are incorporated herein by reference.

### BACKGROUND OF THE INVENTION

1. Field of the Invention

The present invention relates to a flash memory device with an ECC (error correcting code) unit, and more particularly to a flash memory device with a rectifiable redundancy generated by the ECC unit.

2. Description of the Related Art

Compared with other storage materials, flash memory has several advantages, such as anti-shock, nonvolatile, and high density. Flash memory is very widely applied to flash memory devices, such as thumb drives, solid state drives (SSD), compact flash cards (CF), secure digital cards (SD), and multi media cards (MMC).

Basically, flash memory can be categorized to two types, SLC (single level cell) flash memory and MLC (multi level cell) flash memory. In SLC flash memory, each one memory cell can store only one bit of data; but in MLC flash memory, each one memory cell can store more than one bit of data.

The characteristics of SLC flash memory can be listed as: (I) Each page in SLC flash memory is multi-write and data can be written to any page in SLC flash memory. (II) The reliability and maintainability of SLC flash memory is relative high, so as a relative complicate ECC is not needed. (III) The life time of SLC flash memory is relative long and each memory cell can be written about 100 thousands times. (IV) The block erasing time and the page programming time of SLC flash memory is relative short. (V) The price of SLC flash memory is relative high.

The characteristics of the MLC flash memory can be listed as: (I) Each page in MLC flash memory is single-write and data must be written to pages sequentially from low page number to high page number. (II) The reliability and maintainability of MLC flash memory is relative low, so as a relative complicate ECC is needed. (III) The life time of MLC flash memory is relative short and each memory cell can only be written about five thousands times. (IV) The block erasing time and the page programming time of MLC flash memory is relative long. (V) The price of MLC flash memory is relative low but the density of MLC flash memory is relative high.

Because the price of MLC flash memory is much lower than that of SLC flash memory, most flash memory devices in market adopt the MLC flash memories. As mentioned above, each memory cell in MLC flash memories can only be written about five thousands times. Once a portion of memory cells is written and erased too many times and data errors in the portion is then occurred. That is to say, the portion of the memory cells (or the whole block) is determined to be damaged (or bad) memory cells. Therefore some mechanisms, for enhancing the reliability and maintainability (or life time) of MLC flash memories, are developed. The followings are three well-known mechanisms can be adopted to enhance the reliability and maintainability of MLC flash memories.

(I) Bad block management: data will not be store in a block which is damaged and labeled to a bad block, so as the risk of occurring data error is reduced.

(II) Wear leveling: data is evenly assigned to blocks in the MLC flash memory, so as every block in the MLC flash memory has an even life time.

(III) ECC: data errors, generated by the damaged blocks, can be corrected by the ECC, so as the reliability and maintainability of MLC flash memory is enhanced.

FIG. 1 is a functional block diagram depicting a conventional flash memory device with an ECC unit. The flash memory device 10 is connected to a host 30 via a host bus 20, and data can be transmitted between the host 30 and the flash memory device 10 via the host bus 20. The host bus 20 can be a compact flash (CF) bus, a secure digital (SD) bus, a multi media card (MMC) bus, an universal serial bus (USB), or an IEEE1394 bus. The flash memory device 10 comprises a control circuit 12 and a flash memory 16, where the control circuit 12 is connected to the flash memory 16 via an internal bus 18. The control circuit 12 further comprises an ECC unit 14.

When data is ready to be written to the flash memory 16 from the host 30, a redundancy is first generated by the ECC unit 14 based on the data. The redundancy is used to correct the data errors and enable reconstruction of the original data. After the redundancy is generated, a write command is issued to the flash memory 16 from the control circuit 12 and then both the data and the redundancy are together written to the flash memory 16 via the internal bus 18.

FIG. 2 is a scheme illustrating a data block stored in the flash memory device 10 based on the ECC unit depicted in FIG. 1. The data block 40 comprises a data 42 and a redundancy 44. The data 42 is the data originally transmitted to the flash memory device 10 from the host 30 and the redundancy 44 is the data generated by the ECC unit 14 based on the data 42.

As mentioned above, the reliability and maintainability of the flash memory 16 can be enhanced by the redundancy generated by the ECC unit 14. That is, even data errors are occurred in the data 42 due to the flash memory 16 is damaged, the data 42 with data errors can be corrected by the redundancy 44, so as the reliability and maintainability (or life time) of the flash memory 16 is extended. However, the redundancy 44 has a fixed data length and once the data errors are beyond the ability the redundancy 44 can deal with, the reliability and maintainability (or life time) of the flash memory 16 cannot be maintained anymore.

### SUMMARY OF THE INVENTION

Therefore, the present invention relates to a flash memory device with a rectifiable redundancy capable of prolonging reliability and maintainability (or life time) of the flash memory.

The present invention provides a flash memory device connected to a host comprising: a flash memory; and a control circuit comprising a first error correcting code unit and a second error correcting code unit. The data length of a redundancy generated by the second error correcting code unit is longer than the data length of a redundancy generated by the first error correcting code unit. The first error correcting code unit is adopted to process with a data transmitted to the flash memory from the host when a damage risk of the flash memory is lower than a specific value; and the second error correcting code unit is adopted to process with the data transmitted to the flash memory from the host when the damage risk of the flash memory is higher than the specific value.

The present invention provides a control method of a flash memory device with an error correcting code mechanism, comprising steps of: adopting a first error correcting code unit to process with a data transmitted to the flash memory device if a damage risk of a flash memory in the flash memory device is lower than a specific value; and adopting a second error correcting code unit to process with the data if the damage risk of the flash memory is higher than the specific value; wherein the data length of a redundancy generated by the second error correcting code unit is longer than the data length of a redundancy generated by the first error correcting code unit.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a functional block diagram depicting a conventional flash memory device with an ECC unit;

FIG. 2 (prior art) is a scheme illustrating a data block stored in the flash memory device 10 based on the ECC unit depicted in FIG. 1;

FIG. 3 is a functional block diagram illustrating a flash memory device with a rectifiable redundancy of the present invention;

FIG. 4A is a scheme illustrating a data block stored in the flash memory device 50 based on the first ECC unit;

FIG. 4B is a scheme illustrating a data block stored in the flash memory device 50 based on the second ECC unit;

FIG. 5A is a scheme illustrating a data block stored in the flash memory device 50 based on the first ECC unit in another embodiment; and

FIG. 5B is a scheme illustrating a data block stored in the flash memory device 50 based on the first and second ECC units in another embodiment.

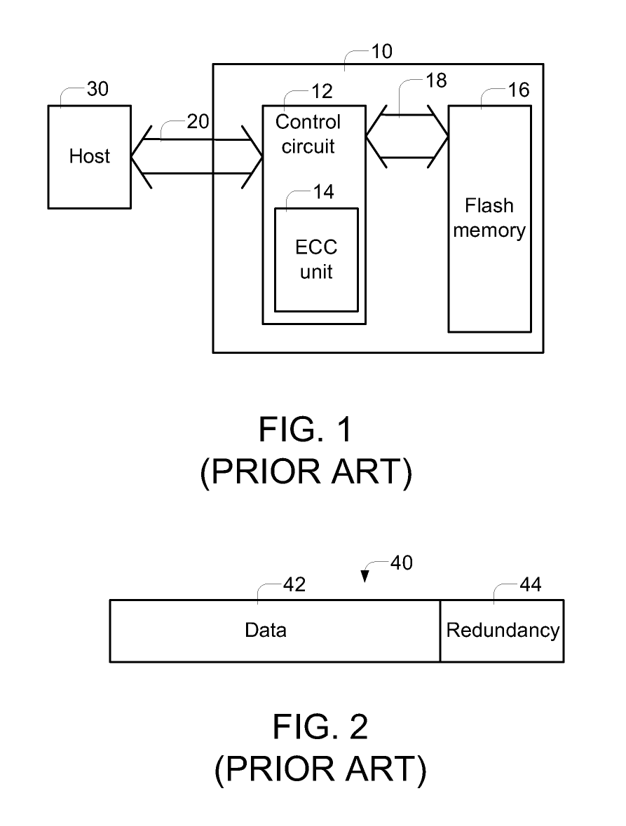

### DETAILED DESCRIPTION OF THE INVENTION

As depicted in FIG. 2, the correcting ability of the ECC to data 42 is related to the data length of the redundancy 44. That is, the ECC has a higher ability to correct the data 42 if the data length of the redundancy 44 is longer. Based on the characteristic of the correcting ability of ECC to data is proportional to the data length of the redundancy, an ECC mechanism with a rectifiable redundancy is introduced in the flash memory device of the present invention. That is, a redundancy with a longer data length is employed in the flash memory device of the present invention once a damage risk of a flash memory in the flash memory device is higher than a specific value. Because the redundancy with a longer data length is employed, the correcting ability of the ECC is accordingly higher, so as the reliability and maintainability (or life time) of the flash memory is enhanced. In the embodiment of the present invention, the damage risk of the flash memory is determined by a count number of damaged blocks in the flash memory or a count number of wear leveling of the flash memory. That is, the damage risk of the flash memory is relative high if the count number of damaged blocks in the flash memory is relative high; or, the damage risk of the flash memory is relative high if the count number of wear leveling of the flash memory is relative high.

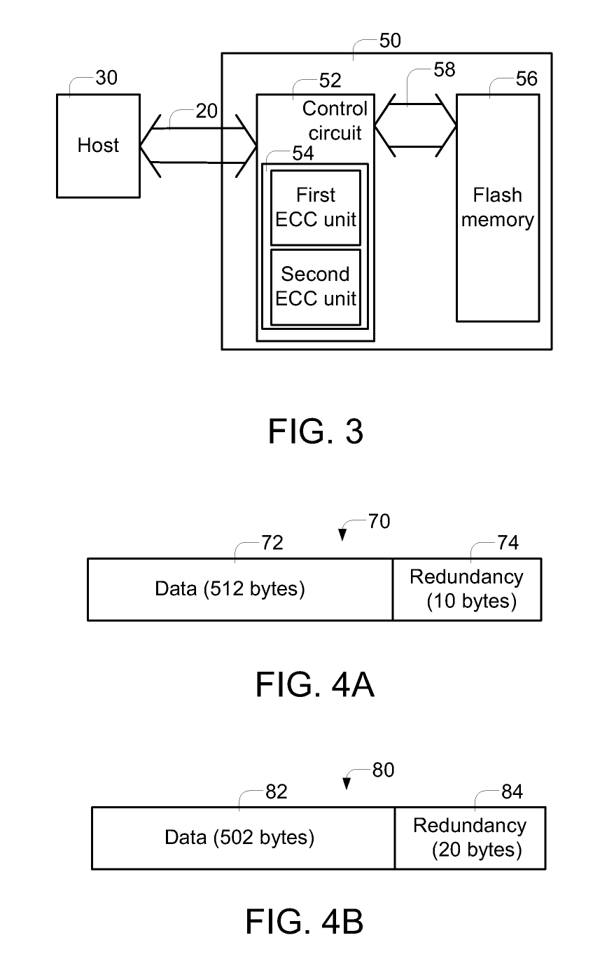

FIG. 3 is a functional block diagram illustrating a flash memory device with a rectifiable redundancy of the present invention. The flash memory device 50 is connected to the host 30 via the host bus 20, and data can be transmitted between the host 30 and the flash memory device 50 via the host bus 20. The flash memory device 50 comprises a control circuit 52 and a flash memory 56, where the control circuit 52 is connected to the flash memory 56 via an internal bus 58. The control circuit 52 comprises an ECC unit 54 which has a first ECC unit and a second ECC unit. The data length of the redundancy generated by the first ECC unit is less than the data length of the redundancy generated by the second ECC unit. It is to be understood that the two redundancies with different data lengths need not be limited to generate by the first and the second ECC units. The two redundancies with different data lengths can be generated by the same ECC unit via a control of a firmware. Moreover, more than two redundancies can be used according to different designs and for higher reliability and maintainability (or life time) of the flash memory.

According to the embodiment of the present invention, a signal (not shown), for informing the ECC unit 54 to employ the first ECC unit, is issued to the ECC unit 54 from the control circuit 52 if the damage risk of the flash memory 56 is determined to be lower than a specific value. The first ECC unit is adopted to process with the data transmitted to the flash memory device 50. FIG. 4A is a scheme illustrating a data block stored in the flash memory device 50 based on the first ECC unit. The data block 70 comprises a data 72 and a redundancy 74. The data block 70 is 522 bytes wherein the data 72 is 512 bytes, and the redundancy 74 is 10 bytes. Moreover, the code rate of the data block 70 is 98% (data length of data 72 (512 bytes) divided by data length of data block 70 (522 bytes)). Moreover, maximum to 4 bytes data error can be corrected by the 10 bytes redundancy 74 if the 10 bytes redundancy 74 is coded by the BCH (Bose, Ray-Chaudhuri, Hocquenghem) code.

With the number of bad blocks (or the number of the wear leveling) of the flash memory 56 getting higher under a constant operation, the damage risk of the flash memory 56 is getting higher. Once the damage risk of the flash memory 56 is determined to be higher than the specific value, a signal, for informing the ECC unit 54 to employ the second ECC unit, is issued to the ECC unit 54 from the control circuit 52. The second ECC unit is adopted to process with the data transmitted to the flash memory device 50. FIG. 4B is a scheme illustrating a data block stored in the flash memory device 50 based on the second ECC unit. The data block 80 comprises a data 82 and a redundancy 84. The data block 80 is 522 bytes wherein the data 82 is 502 bytes, and the redundancy 84 is 20 bytes. Moreover, the code rate of the data block 80 is 96% (data length of data 82 (502 bytes) divided by data length of data block 80 (522 bytes)). Moreover, maximum to 8 bytes data error can be corrected by the 20 bytes redundancy 84 if the redundancy 84 is coded by the BCH code. Therefore, the reliability and maintainability (or life time) of the flash memory 56 is enhanced by increasing the data length of the redundancy.

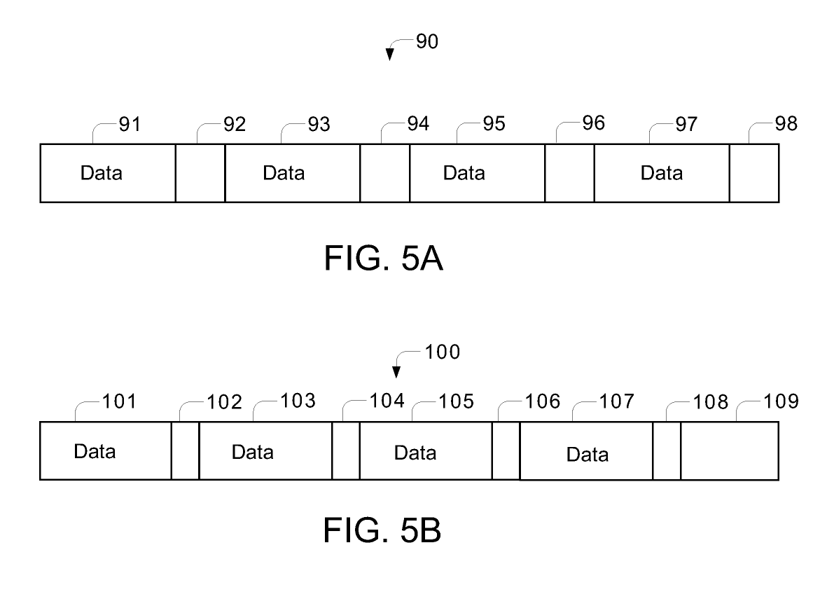

According to another embodiment of the present invention, a signal (not shown), for informing the ECC unit 54 to employ the first ECC unit, is issued to the ECC unit 54 from the control circuit 52 if the damage risk of the flash memory 56 is determined to be lower than a specific value. The first ECC unit is adopted to process with the data transmitted to the flash memory device 50. FIG. 5A is a scheme illustrating a data block stored in the flash memory device 50 based on the first ECC unit. The data block 90 comprises a plurality of pages. Each page comprises the user data and redundancy. For example, the first page comprises a data 91 and a redundancy 92, second page comprises a data 93 and a redundancy 94, etc. The first page size is 522 bytes wherein the data 91 is 512 bytes, and the redundancy 92 is 10 bytes. Moreover, the code rate of the first page is 98% (data length of data 91 (512 bytes) divided by page size (522 bytes)). BCH code can correct maximum to 4 bytes data error.

With the number of bad blocks (or the number of the wear leveling) of the flash memory 56 getting higher under a constant operation, the damage risk of the flash memory 56 is getting higher. Once the damage risk of the flash memory 56 is determined to be higher than the specific value, a signal, for informing the ECC unit 54 to additionally employ the second ECC unit, is issued to the ECC unit 54 from the control circuit 52. The second ECC unit is also adopted to process with the data transmitted to the flash memory device 50. FIG. 5B is a scheme illustrating a data block stored in the flash memory device 50 based on the first and second ECC units. The data block 100 comprises a data 101 and a redundancy 102, etc. Furthermore, the data block 100 comprises a redundancy 109. The redundancy 102, 104, 106, 108 are generated from the first ECC unit and the redundancy 109 is generated from the second ECC unit. The data length of data 101, 103, 105, and 107 and its redundancy 102, 104, 106, 108 of the data block 100 is shorter than the data length and redundancy of data block 90 shown in FIG. 5A such that there is a spared space for storing the redundancy 109. The redundancy 109 is generated by the second ECC unit according to the XOR result of data 101, 103, 105 and 107.

The length of the redundancy generated by the first ECC unit is less than that of the redundancy generated by the second ECC unit. The errors of data block 100 comprising the redundancies can be corrected by first ECC unit and/or second ECC unit. Therefore, the reliability and maintainability (or life time) of the flash memory 56 is enhanced by combining the redundancies generated by first and second ECC units.

In the embodiments of FIGS. 5A and 5B, though it is illustrated that the data block comprises a plurality of pages, it is to be understood that the “page” can mean any unit of data group. For example, sector unit or block unit.

To sum up, if a damage risk of a flash memory is lower than a specific value when a count number of damaged blocks (or, a count number of wear leveling) in the flash memory is lower than a specific value, a first ECC unit with a shorter redundancy is adopted to process with the data transmitted to the flash memory device. However, once the damage risk of the flash memory is higher than a specific value under a constant operation and the first ECC unit with a shorter redundancy may fail to correct the data errors, a second ECC unit with a longer redundancy is adopted to process with the data transmitted to the flash memory device, so as the reliability and maintainability of the flash memory is enhanced and the life time of the flash memory is extended.

Moreover, it is to be understood that the present invention needs not be limited to the MLC flash memory. The present invention can be also applied to other types of flash memory, such as SLC flash memory.

Moreover, it is to be understood that the present invention needs not be limited to adopt the BCH code. Other types of ECC, such as Hamming code, Reed-Solomon code or other linear block codes, can be adopted in the present invention. Or, the first ECC unit and the second ECC unit can use the same encoding code but with different encoding length.

Moreover, it is to be understood that the damage risk needs not be limited to determine by the count number of damaged blocks or the count number of the wear leveling in the flash memory. Other determining mechanisms can be adopted in the present invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A flash memory device connected to a host comprising:
a flash memory; and
a control circuit comprising a first error correcting code unit and a second error correcting code unit, wherein the data length of a redundancy generated by the second error correcting code unit is longer than the data length of a redundancy generated by the first error correcting code unit;
wherein the first error correcting code unit is adopted to process with a data transmitted to the flash memory from the host when a damage risk of the flash memory is lower than a specific value; and the first and second error correcting code units are adopted to process with the data transmitted to the flash memory from the host when the damage risk of the flash memory is higher than the specific value,
wherein when the first and second error correcting code units are adopted, the redundancy generated by the second error correcting code unit is generated according to a XOR result of the data which is processed by the first error correcting code unit.

2. The flash memory device according to claim 1 wherein the damage risk of the flash memory is determined by a count number of damaged blocks in the flash memory.

3. The flash memory device according to claim 1 wherein the damage risk of the flash memory is determined by a count number of wear leveling in the flash memory.

4. The flash memory device according to claim 1 wherein the first error correcting code unit and the second error correcting code unit use at least one of BCH code, Hamming code, or Reed-Solomon code to generate the redundancy.

5. The flash memory device according to claim 1 wherein the flash memory is a multi-level-cell (MLC) flash memory.

6. A control method of a flash memory device with an error correcting code mechanism, comprising steps of:
adopting a first error correcting code unit to process with a data transmitted to the flash memory device if a damage risk of a flash memory in the flash memory device is lower than a specific value; and
adopting a second error correcting code unit and the first error correcting code unit to process with the data if the damage risk of the flash memory is higher than the specific value;
wherein the data length of a redundancy generated by the second error correcting code unit is longer than the data length of a redundancy generated by the first error correcting code unit,
wherein when the first and second error correcting code units are adopted, the redundancy generated by the second error correcting code unit is generated according to a XOR result of the data which is processed by the first error correcting code unit.

7. The method according to claim 6 wherein the damage risk of the flash memory is determined by a count number of damaged blocks in the flash memory.

8. The method according to claim 6 wherein the damage risk of the flash memory is determined by a count number of wear leveling in the flash memory.

9. The method according to claim 6 wherein the first error correcting code unit and the second error correcting code unit use at least one of BCH code, Hamming code, or Reed-Solomon code to generate the redundancy.

10. The method according to claim 6 wherein the flash memory is a multi-level-cell (MLC) flash memory.
